(19) United States
(12) Patent Application Publication
(10) Pub. No.: US 2026/0110756 A1
(43) Pub. Date: Apr. 23, 2026

(54) METHOD AND SYSTEM FOR CALCULATING MAGNETIC FLUX DENSITY DISTRIBUTION OF NANOCRYSTALLINE CORE, MEDIUM, AND DEVICE

(71) Applicant: XI’AN JIAOTONG UNIVERSITY, Xi'an (CN)

(72) Inventors: Lingyu ZHU, Xi'an (CN); Zhanlei LIU, Xi'an (CN); Yongliang DANG, Xi'an (CN); Shengchang JI, Xi'an (CN)

(21) Appl. No.: 19/354,439

(22) Filed: Oct. 9, 2025

(30) Foreign Application Priority Data
Oct. 10, 2024 (CN) 2024114088435

(51) Int. Cl. G01R 33/02; G01R 31/52; G01R 31/54

(52) U.S. Cl. CPC G01R 33/02; G01R 31/52; G01R 31/54

(57) ABSTRACT

Disclosed are a method and system for calculating a magnetic flux density distribution in a nanocrystalline high-frequency transformer core under a load condition, a medium, and a device. In the method, a magnetic flux density under a load condition is decomposed into a magnetic flux density under an open-circuit condition and a magnetic flux density under a short-circuit condition that are subjected to superposition. The magnetic flux density in the nanocrystalline core under an open-circuit condition and the magnetic flux density in the nanocrystalline core under a short-circuit condition are merely simulated through frequency domain finite element simulation, and then subjected to superposition calculation to obtain the magnetic flux density distribution in the nanocrystalline core under a load condition. Time domain finite element simulation calculation is omitted, and therefore simulation calculation time is greatly shortened, and calculation efficiency is improved.

### CROSS-REFERENCE TO RELATED APPLICATION

This application claims priority from the Chinese patent application 2024114088435 filed Oct. 10, 2024, the content of which is incorporated herein in the entirety by reference.

### TECHNICAL FIELD

The present disclosure relates to the technical field of nanocrystalline high-frequency transformers, and in particular, to a method and system for calculating a magnetic flux density distribution in a nanocrystalline high-frequency transformer core under a load condition, a medium, and a device.

### BACKGROUND

Accurate calculation of a core loss of a high-frequency transformer is essential for efficiency evaluation and heat dissipation design of the high-frequency transformer. Since the core loss density is closely related to the magnetic flux density, the accurate calculation of the core loss depends on accurate calculation of a magnetic flux density distribution in a core.

The magnetic flux density distribution in the core can be calculated by a finite element simulation method. Since ferrite is a type of homogeneous material, a ferrite core has isotropic electrical conductivity and magnetic conductivity parameters, and the ferrite can be subjected to tetrahedral mesh generation directly during finite element simulation. A nanocrystalline core is formed by winding a strip, and has a multi-layer material composite structure composed of a nanocrystalline strip and an epoxy resin insulation layer, and the nanocrystalline strip and the epoxy resin insulation layer both have extremely small thicknesses. Refined mesh generation on the strip layer and the insulation layer will lead to a large amount of model calculation. In view of that, a homogenized finite element modeling method is provided in the prior art, the multi-layer composite nanocrystalline core is equivalent to a homogeneous entity, and the equivalent nanocrystalline core entity has anisotropic electrical conductivity and magnetic conductivity features. In the prior art, frequency domain simulation is performed on a magnetic flux density distribution in the nanocrystalline core under an open-circuit condition based on the homogenized modeling method. Since the magnetic flux density distribution under an open-circuit condition is uniform, free tetrahedral mesh generation can be adopted. In the prior art, frequency domain simulation is performed on a magnetic flux density distribution in the nanocrystalline core under a short-circuit condition based on the homogenized modeling method. Since the magnetic flux density distribution under a short-circuit condition is concentrated on a surface strip, it is necessary to perform refined mesh generation on the surface strip of the core. For simulation of a magnetic flux density distribution in the nanocrystalline core under a load condition based on the homogenized modeling method, refined mesh generation and time domain simulation calculation are required, resulting in a huge amount of calculation. At present, no relevant methods can be used for accurately and efficiently calculating the magnetic flux density distribution in the nanocrystalline core under a load condition.

The information disclosed in the background is merely for the convenience of understanding the background of the present disclosure, and may include information excluded from the prior art known to those of ordinary skill in the art.

### SUMMARY

In order to solve the shortcomings in the prior art, an objective of the present disclosure is to provide a method and system for calculating a magnetic flux density distribution in a nanocrystalline high-frequency transformer core under a load condition, a medium, and a device for accurately and efficiently obtaining the magnetic flux density of the nanocrystalline core under a load condition.

In order to achieve the above objective, the present disclosure provides the following technical solution:

A method for calculating a magnetic flux density distribution in a nanocrystalline high-frequency transformer core under a load condition includes:

characterizing, under a load condition, an average magnetic flux density passing through a section S in the nanocrystalline high-frequency transformer core by adopting an equivalent magnetization voltage, where a magnetic flux □_{load} in the nanocrystalline core under a load condition is equal to a sum of a main flux □ₘₐᵢₙ under an open-circuit condition and a leakage flux □_{leakage} under a short-circuit condition, that is, φ_{load}=φₘₐᵢₙ+φ_{leakage}, and an EMVu_{m,load} of a particular section S of the nanocrystalline core under a load condition is equal to a sum of an EMVu_{m,open} of the section under an open-circuit condition and an EMVu_{m,short} of the section under a short-circuit condition, that is,

$${u}_{m , load} = {u}_{m , open} + {u}_{m , short} ;$$

expressing, based on Fourier superposition principle, an open circuit voltage uₒₚₑₙ and a short circuit voltage uₛₕₒᵣₜ as follows:

$$\begin{matrix}{u}_{open} = {\sum }_{i = 1}^{n} {u}_{open , sin , n} , & {u}_{s h o r t} = {\sum }_{i = 1}^{n} {u}_{s h o r t , s i n , n}\end{matrix}$$

in the formula, u_{open,sin,n} denotes an n^{th} harmonic component of the open circuit voltage, and u_{short,sin,n} denotes an n^{th} harmonic component of the short circuit voltage, and an EMVu_{m,open,n} under n^{th} harmonic excitation of the open circuit voltage and an EMVu_{m,short,n} under n^{th} harmonic excitation of the short circuit voltage are expressed as follows:
u_{m,open,n}=k₁u_{open,sin,n}, u_{m,short,n}=k₂u_{short,sin,n}, in the formula, k₁ denotes a coefficient related to a main flux distribution in the core under open-circuit sinusoidal excitation, and k₂ denotes a coefficient related to a leakage flux distribution in the core under short-circuit sinusoidal excitation, and an EMV under an open-circuit condition and an EMV under a short-circuit condition are expressed as follows:

$${u}_{m , o p e n} = {\sum }_{i = 1}^{n} {u}_{m , o p e n , n} = {k}_{1} {\sum }_{i = 1}^{n} {u}_{o p e n , s i n , n} = {k}_{1} {u}_{o p e n} ,$$

$${u}_{m , short} = {\sum }_{i = 1}^{n} {u}_{m , short , n} = {k}_{2} {\sum }_{i = 1}^{n} {u}_{short , sin , n} = {k}_{2} {u}_{s h o r t} ,$$

and
the EMV of the section S in the nanocrystalline core under a load condition is expressed as follows:

$${u}_{m , load} = {k}_{1} {u}_{open} + {k}_{2} {u}_{short} ;$$

and
expressing, through an integral operation, the average magnetic flux density in the section S in the core as follows:

$${B}_{a v e} ( t ) = \frac{1}{S} \int {u}_{m , load} d t = \frac{1}{S} \int ( {k}_{1} {u}_{o p e n} + {k}_{2} {u}_{short} ) dt .$$

In the method, when an area S of the section S of the core approaches zero,

$$\begin{matrix}B ( t ) = {lim}_{S \to 0} \frac{1}{S} \int ( {k}_{1} {u}_{open} + {k}_{2} {u}_{short} ) d t \\ = {lim}_{S \to 0} \frac{1}{S} \int ( {k}_{1} {u}_{open} dt + {k}_{2} {u}_{short} dt ) \\ = {lim}_{S \to 0} \frac{1}{S} ( {k}_{1} {ψ}_{open} + {k}_{2} {ψ}_{short} ) \\ = ( {k}_{11} {ψ}_{open} + {k}_{22} {ψ}_{short} )\end{matrix} ,$$

in the formula, ψₒₚₑₙ and ψₛₕₒᵣₜ denote a total flux linkage under an open-circuit condition and a total flux linkage under a short-circuit condition respectively, a coefficient k₁₁ is a coefficient related to a main flux density distribution in the core under the open-circuit sinusoidal excitation, and a coefficient k₂₂ is a coefficient related to a leakage flux density distribution in the core under the short-circuit sinusoidal excitation.

In the method, the equivalent magnetization voltage (EMV) is expressed as follows:

$${u}_{m} ( t ) = \frac{d ϕ ( t )}{d t} = \frac{d}{d t} \int B ( t ) dS = S \frac{d {B}_{a v e} ( t )}{d t}$$

in the formula, uₘ(t) denotes the equivalent magnetization voltage of the section S of the core, □(t) denotes a magnetic flux passing through the section, B(t) denotes a magnetic flux density, Bₐᵥₑ(t) denotes the average magnetic flux density in the section, and S denotes an area of the section S of the core.

In the method, the coefficient k₁, the coefficient k₂, the coefficient k₁₁, and the coefficient k₂₂ are calculated through finite element simulation, a magnetic flux density distribution in the nanocrystalline core under an open-circuit condition and a magnetic flux density distribution in the nanocrystalline core under a short-circuit condition are calculated through frequency domain simulation at first, and then an amplitude Uₘ of the equivalent magnetization voltage (EMV) of the section of the core is calculated as follows:

$${U}_{m} = ω {ϕ}_{m} = ω \int {B}_{m} \cdot dS = 2 π f \int {B}_{m} \cdot dS ,$$

in the formula, f denotes a frequency, □ₘ denotes a magnetic flux amplitude, Bₘ denotes a magnetic flux density amplitude, S denotes the area of the section of the core, and
k₁, k₂, k₁₁, and k₂₂ are expressed as follows:

$${k}_{1} = {U}_{m , open} / {U}_{sin , open} ,$$

$${k}_{2} = {U}_{m , shot} / {U}_{sin , short} ,$$

$${k}_{11} = {lim}_{S \to 0} \frac{{k}_{1}}{S} = {lim}_{S \to 0} \frac{{U}_{m , open} / S}{{U}_{sin , open}} = \frac{{B}_{m , open}}{{ψ}_{m , open}} ,$$

$${k}_{22} = {lim}_{S \to 0} \frac{{k}_{2}}{S} = {lim}_{S \to 0} \frac{{U}_{m , short} / S}{{U}_{sin , short}} = \frac{{B}_{m , short}}{{ψ}_{m , short}} ,$$

in the formula, U_{m,open} and U_{m,short} denote an EMV amplitude calculated under an open-circuit condition and an EMV amplitude calculated under a short-circuit condition respectively, B_{m,open} and B_{m,short} denote a magnetic flux density amplitude calculated under an open-circuit condition and a magnetic flux density amplitude calculated under a short-circuit condition respectively, U_{sin,open} and U_{sin,short} denote an open-circuit excitation voltage amplitude and a short-circuit excitation voltage amplitude respectively, and ψ_{m,open} and ψ_{m,short} denote a flux linkage amplitude under an open-circuit condition and a flux linkage amplitude under a short-circuit condition respectively.

In the method, the nanocrystalline core is modeled based on a homogenized solid body instead of a layered stacked structure, and an anisotropic magnetic conductivity and an electrical conductivity of the core are expressed as follows:

$$\{ \begin{matrix}{μ}_{τ} = {μ}_{d} = F {μ}_{m} + ( 1 - F ) {μ}_{0} \\ {μ}_{n} = \frac{{μ}_{0} {μ}_{m}}{( 1 - F ) {μ}_{m} + F {μ}_{0}}\end{matrix} ,$$

$$\{ \begin{matrix}{σ}_{t} = {σ}_{d} = f {σ}_{m} \\ {σ}_{n} = {( \frac{d}{D} )}^{2} \frac{1}{F} {σ}_{m}\end{matrix} ,$$

in the formula, μᵣ, μ_{d}, and μₐ denote an equivalent magnetic conductivity of the nanocrystalline core in a winding direction, an equivalent magnetic conductivity of the nanocrystalline core in a thickness direction, and an equivalent magnetic conductivity of the nanocrystalline core in a normal direction respectively, σᵣ, σ_{d}, and σₙ denote an equivalent electrical conductivity of the nanocrystalline core in the winding direction, an equivalent electrical conductivity of the nanocrystalline core in the thickness direction, and an equivalent electrical conductivity of the nanocrystalline core in the normal direction respectively, F denotes a filling coefficient, μ₀ denotes a magnetic conductivity in vacuum, μₘ denotes a magnetic conductivity of a strip, om denotes an electrical conductivity of the strip, d denotes a thickness of the strip, and D denotes a width of the core.

A system for calculating a magnetic flux density distribution in a nanocrystalline high-frequency transformer core under a load condition includes:
a load measuring unit configured to characterize, under a load condition, an average magnetic flux density passing through a section S in the nanocrystalline high-frequency transformer core by adopting an equivalent magnetization voltage, where a magnetic flux □_{load} in the nanocrystalline core under a load condition is equal to a sum of a main flux □ₘₐᵢₙ under an open-circuit condition and a leakage flux □_{leakage} under a short-circuit condition, that is, φ_{load}=φₘₐᵢₙ+φ_{leakage}, and an EMVu_{m,load} of a particular section S of the nanocrystalline core under a load condition is equal to a sum of an EMVu_{m,open} of the section under an open-circuit condition and an EMVu_{m,short} of the section under a short-circuit condition, that is, u_{m,load}=u_{m,open}+u_{m,short};
a voltage calculating unit configured to calculate, based on Fourier superposition principle, an open circuit voltage uₒₚₑₙ and a short circuit voltage uₛₕₒᵣₜ, where the open circuit voltage uₒₚₑₙ and the short circuit voltage uₛₕₒᵣₜ are expressed as follows:

$${u}_{o p e n} = {\sum }_{i = 1}^{n} {u}_{o p e n , s i n , n} , {u}_{short} = {\sum }_{i = 1}^{n} {u}_{short , sin , n}$$

in the formula, u_{open,sin,n} denotes an n^{th} harmonic component of the open circuit voltage, and u_{short,sin,n} denotes an n^{th} harmonic component of the short circuit voltage, and an EMVu_{m,open,n} under n^{th} harmonic excitation of the open circuit voltage and an EMVu_{m,short,n} under n^{th} harmonic excitation of the short circuit voltage are expressed as follows:
u_{m,open,n}=k₁u_{open,sin,n}, u_{m,short,n}=k₂u_{short,sin,n}, in the formula, k₁ denotes a coefficient related to a main flux distribution in the core under open-circuit sinusoidal excitation, and k₂ denotes a coefficient related to a leakage flux distribution in the core under short-circuit sinusoidal excitation, and an EMV under an open-circuit condition and an EMV under a short-circuit condition are expressed as follows:

$${u}_{m , o p e n} = {\sum }_{i = 1}^{n} {u}_{m , o p e n , n} = {k}_{1} {\sum }_{i = 1}^{n} {u}_{o p e n , s i n , n} = {k}_{1} {u}_{o p e n} ,$$

$${u}_{m , short} = {\sum }_{i = 1}^{n} {u}_{m , s h o r t , n} = {k}_{2} {\sum }_{i = 1}^{n} {u}_{short , sin , n} = {k}_{2} {u}_{s h o r t} ,$$

and
the EMV of the section S in the nanocrystalline core under a load condition is expressed as follows:

$${u}_{m , load} = {k}_{1} {u}_{open} + {k}_{2} {u}_{short} ;$$

and
an integral unit configured to express, through an integral operation, the average magnetic flux density in the section S in the core as follows:

$${B}_{a v e} ( t ) = \frac{1}{S} \int {u}_{m , load} d t = \frac{1}{S} \int ( {k}_{1} {u}_{o p e n} + {k}_{2} {u}_{short} ) dt .$$

In the system, the integral unit includes a finite element simulation unit for calculating the average magnetic flux density in the section S of the core.

In the system, the finite element simulation unit is COMSOL Multiphysics, Ansys, or Maxwell.

A computer storage medium includes computer instructions, where the computer instructions cause a computer to perform the method when run on the computer.

### An Electronic Device Includes:

a memory, a processor, and a computer program that is stored in the memory and is runnable on the processor, where the processor implements the method when executing the program.

### Beneficial Effects

According to the method for calculating a magnetic flux density distribution in a nanocrystalline high-frequency transformer core under a load condition, a magnetic flux density under a load condition is decomposed into a magnetic flux density under an open-circuit condition and a magnetic flux density under a short-circuit condition that are subjected to superposition. The magnetic flux density in the nanocrystalline core under an open-circuit condition and the magnetic flux density in the nanocrystalline core under a short-circuit condition are merely simulated through frequency domain finite element simulation, and subjected to superposition calculation to obtain the magnetic flux density distribution in the nanocrystalline core under a load condition. Time domain finite element simulation calculation is omitted, and therefore simulation calculation time is greatly shortened, and calculation efficiency is improved.

What is described above is merely an overview of the technical solution of the present disclosure. In order to make the technical means of the present disclosure so clear and understandable that those of ordinary skill in the art can implement the technical means according to the contents of the description, and to make the foregoing and other objectives, features, and advantages of the present disclosure more apparent and comprehensible, description will be given blow with specific implementations of the present disclosure as examples.

### BRIEF DESCRIPTION OF DRAWINGS

To describe technical solutions in embodiments of the present disclosure or in the prior art more clearly, accompanying drawings required in the embodiments will be described briefly below. Apparently, the accompanying drawings in the following description merely show some embodiments described in the present disclosure, and those of ordinary skill in the art can still derive other accompanying drawings from these accompanying drawings.

Other various advantages and benefits of the present disclosure will become apparent to those of ordinary skill in the art by reading the following detailed description of the preferred specific implementations. The accompanying drawings of the description are merely for illustrating the preferred implementations, but should not be considered as limitation to the present disclosure. Apparently, the accompanying drawings in the following descriptions merely show some embodiments of the present disclosure, and those of ordinary skill in the art can still derive other accompanying drawings from the accompanying drawings without creative efforts. Throughout the accompanying drawings, identical reference numerals refer to identical components.

### In the Figures:

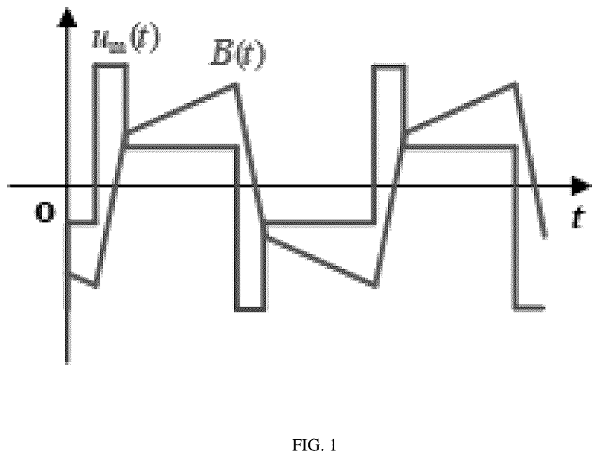

FIG. 1 is a schematic diagram of time domain waveforms of uₘ(t) and B(t) of a method for calculating a magnetic flux density distribution in a nanocrystalline high-frequency transformer core under a load condition according to the present disclosure;

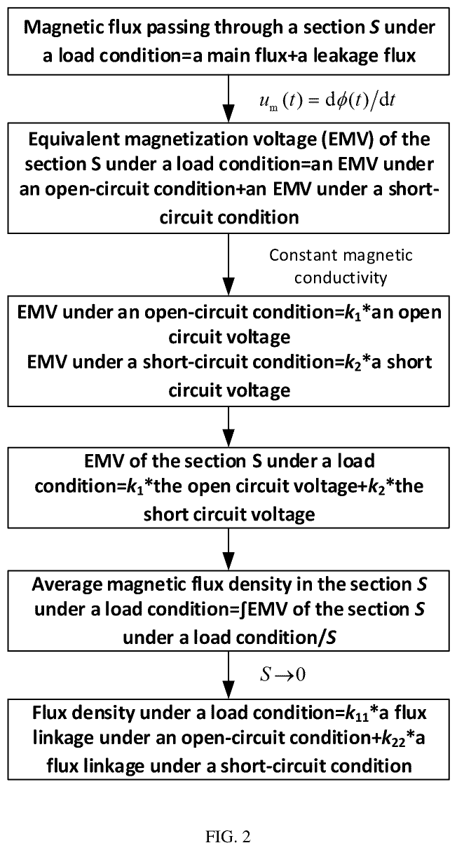

FIG. 2 is a schematic diagram of steps of a method for calculating a magnetic flux density distribution in a nanocrystalline high-frequency transformer core under a load condition according to the present disclosure;

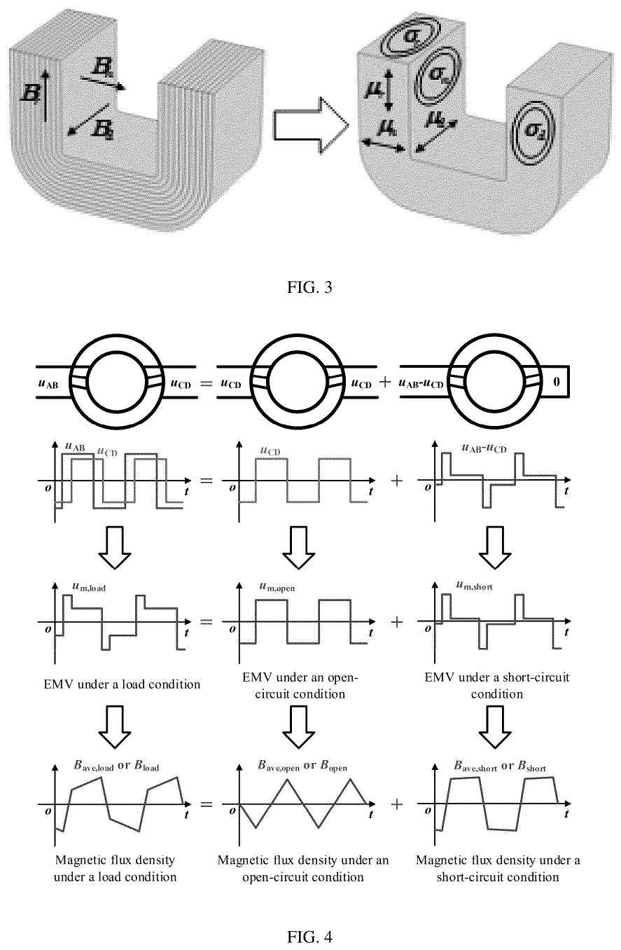

FIG. 3 is a schematic diagram of a homogenized model of a nanocrystalline core of a method for calculating a magnetic flux density distribution in a nanocrystalline high-frequency transformer core under a load condition according to the present disclosure; and

FIG. 4 is a schematic diagram of a calculation process of an equivalent magnetization voltage (EMV) and a magnetic flux density under a single-phase-shift dual-active-bridge (DAB) load condition of a method for calculating a magnetic flux density distribution in a nanocrystalline high-frequency transformer core under a load condition according to the present disclosure.

The present disclosure will be further explained below with reference to the accompanying drawings and in conjunction with the embodiments.

### DETAILED DESCRIPTION OF THE INVENTION

To make objectives, technical solutions, and advantages of implementations of the present disclosure clearer, the technical solutions in the implementations of the present disclosure will be clearly and completely described below in conjunction with the implementations of the present disclosure. Apparently, the implementations described are some implementations rather than all implementations of the present disclosure. All the other implementations derived by those of ordinary skill in the art from the implementations of the present disclosure without creative efforts should fall within the protection scope of the present disclosure.

Thus, the detailed description of the implementations of the present disclosure as provided in the accompanying drawings below is not intended to limit the protection scope claimed by the present disclosure, but merely denotes selected implementations of the present disclosure. All the other implementations derived by those of ordinary skill in the art from the implementations of the present disclosure without creative efforts should fall within the protection scope of the present disclosure.

It should be noted that since similar reference numerals and letters indicate similar items in the following accompanying drawings, once defined in one accompanying drawing, an item does not need to be further defined and explained in subsequent accompanying drawings.

In the description of the present disclosure, it should be understood the orientation or positional relationships indicated by the terms “center”, “longitudinal”, “lateral”, “length”, “width”, “thickness”, “up”, “down”, “front”, “rear”, “left”, “right”, “vertical”, “horizontal”, “top”, “bottom”, “inside”, “outside”, “clockwise”, “counterclockwise”, etc. are based on the orientation or positional relationship shown in the accompanying drawings, are merely for facilitating the description of the present disclosure and simplifying the description, rather than indicating or implying that a device or element referred to must have a specific orientation or be constructed and operated in a specific orientation, and thus should not be interpreted as limitation to the present disclosure.

In addition, the terms such as “first” and “second” are used for descriptive purposes merely, and cannot be construed as indicating or implying relative importance or implicitly indicating the number of technical features indicated. Thus, features defined with “first” and “second” can explicitly or implicitly include one or more of the features. In the description of the present disclosure, “plurality” means two or more, unless otherwise specifically limited explicitly.

In the present disclosure, unless otherwise clearly specified, the terms such as “mount”, “connected”, “connection”, and “fix” should be understood broadly. For example, they can denote a fixed connection, a detachable connection, or an integrated connection, can be a direct connection or an indirect connection through an intermediate medium, and can be internal communication of two elements or interaction between two elements. Those of ordinary skill in the art can understand specific meanings of the above terms in the present disclosure based on a specific situation.

In the present disclosure, unless otherwise specified and limited, a first feature “above” or “below” a second feature indicates that the first feature may be in direct contact with the second feature, or may be in indirect contact with the second feature through another feature therebetween. Further, the first feature “above”, “over”, and “on” the second feature indicates that the first feature is exactly above or obliquely above the second feature, or merely indicates that the first feature is higher than the second feature in horizontal height. The first feature “below”, “under”, and “on a bottom of” the second feature indicates that the first feature is exactly below or obliquely below the second feature, or merely indicates that the first feature is lower than the second feature in horizontal height.

In order to make those of ordinary skill in the art better understand the technical solution of the present disclosure, the present disclosure will be further described in detail with reference to the accompanying drawings, and the accompanying drawings do not constitute limitation to the embodiments of the present disclosure.

In an embodiment, as shown in FIG. 1 to FIG. 4, the present disclosure provides a method for calculating a magnetic flux density distribution in a nanocrystalline high-frequency transformer core under a load condition. The method includes:
under a load condition, an average magnetic flux density passing through a section S in the nanocrystalline high-frequency transformer core is characterized by adopting an equivalent magnetization voltage, and the equivalent magnetization voltage (EMV) is expressed as follows:

$${u}_{m} ( t ) = \frac{d ϕ ( t )}{d t} = \frac{d}{d t} \int B ( t ) d S = S \frac{d {B}_{a v e} ( t )}{d t} \qquad ( 1 )$$

In the formula, uₘ(t) denotes the equivalent magnetization voltage of the section S of the core, □(t) denotes a magnetic flux passing through the section, B(t) denotes a magnetic flux density, Bₐᵥₑ(t) denotes the average magnetic flux density in the section, and S denotes an area of the section S of the core;
a magnetic flux □_{load} in the nanocrystalline core under a load condition is equal to a sum of a main flux □ₘₐᵢₙ under an open-circuit condition and a leakage flux □_{leakage} under a short-circuit condition, that is,

$${ϕ}_{load} = {ϕ}_{main} + {ϕ}_{leakage} \qquad ( 2 )$$

an EMVu_{m,load} of a particular section S of the nanocrystalline core under a load condition is equal to a sum of an EMVu_{m,open} of the section under an open-circuit condition and an EMVu_{m,short} of the section under a short-circuit condition, that is,

$${u}_{m , load} = {u}_{m , open} + {u}_{m , short} \qquad ( 3 )$$

based on Fourier superposition principle, an open circuit voltage uₒₚₑₙ and a short circuit voltage uₛₕₒᵣₜ are expressed as follows:

$${u}_{open} = {\sum }_{i = 1}^{n} {u}_{open , sin , n} \qquad ( 4 )$$

$${u}_{short} = {\sum }_{i = 1}^{n} {u}_{short , sin , n} \qquad ( 5 )$$

In the formula, u_{open,sin,n} denotes an n^{th} harmonic component of the open circuit voltage, and u_{short,sin,n} denotes an n^{th} harmonic component of the short circuit voltage, and an EMVu_{m,open,n} under n^{th} harmonic excitation of the open circuit voltage and an EMVu_{m,short,n} under n^{th} harmonic excitation of the short circuit voltage are expressed as follows:

$${u}_{m , open , n} = {k}_{1} {u}_{open , sin , n} \qquad ( 6 )$$

$${u}_{m , s h o r t , n} = {k}_{2} {u}_{s h o r t , s i n , n} \qquad ( 7 )$$

In the formula, k₁ denotes a coefficient related to a main flux distribution in the core under open-circuit sinusoidal excitation, and k₂ denotes a coefficient related to a leakage flux distribution in the core under short-circuit sinusoidal excitation, and by combining Formula (4) to Formula (7), an EMV under an open-circuit condition and an EMV under a short-circuit condition are expressed as follows:

$${u}_{m , o p e n} = {\sum }_{i = 1}^{n} {u}_{m , o p e n , n} = {k}_{1} {\sum }_{i = 1}^{n} {u}_{o p e n , s i n , n} = {k}_{1} {u}_{o p e n} \qquad ( 8 )$$

$${u}_{m , short} = {\sum }_{i = 1}^{n} {u}_{m , s h o r t , n} = {k}_{2} {\sum }_{i = 1}^{n} {u}_{short , sin , n} = {k}_{2} {u}_{s h o r t} \qquad ( 9 )$$

By combining Formula (3), Formula (8), and Formula (9), the EMV of the section S in the nanocrystalline core under a load condition is expressed as follows:

$${u}_{m , load} = {k}_{1} {u}_{o p e n} + {k}_{2} {u}_{short} ; \qquad ( 10 )$$

and
through an integral operation, the average magnetic flux density in the section S in the core is expressed as follows:

$${B}_{a v e} ( t ) = \frac{1}{S} \int {u}_{m , load} d t = \frac{1}{S} \int ( {k}_{1} {u}_{o p e n} + {k}_{2} {u}_{short} ) d t \qquad ( 11 )$$

When an area S of the section S of the core approaches zero, Formula (11) is changed into

$$\begin{matrix}B ( t ) = {lim}_{S \to 0} \frac{1}{S} \int ( {k}_{1} {u}_{open} + {k}_{2} {u}_{short} ) dt \\ = {lim}_{S \to 0} \frac{1}{S} \int ( {k}_{1} {u}_{open} dt + {k}_{2} {u}_{short} dt ) \\ = {lim}_{S \to 0} \frac{1}{S} ( {k}_{1} {ψ}_{open} + {k}_{2} {ψ}_{short} ) \\ = ( {k}_{11} {ψ}_{open} + {k}_{22} {ψ}_{short} )\end{matrix} \qquad ( 12 )$$

In the formula, Vis and denote a total flux linkage under an open-circuit condition and a total flux linkage under a short-circuit condition respectively, a coefficient k₁₁ is a coefficient related to a main flux density distribution in the core under the open-circuit sinusoidal excitation, and a coefficient k₂₂ is a coefficient related to a leakage flux density distribution in the core under the short-circuit sinusoidal excitation.

In a preferred implementation of the method, the coefficient k₁, the coefficient k₂, the coefficient k₁₁, and the coefficient k₂₂ are calculated through finite element simulation, a magnetic flux density distribution in the nanocrystalline core under an open-circuit condition and a magnetic flux density distribution in the nanocrystalline core under a short-circuit condition are calculated through frequency domain simulation at first, and then through Formula (13), an amplitude Uₘ of the equivalent magnetization voltage (EMV) of the section of the core is calculated as follows:

$${U}_{m} = {ωϕ}_{m} = ω \int {B}_{m} \cdot dS = 2 π f \int {B}_{m} \cdot dS \qquad ( 13 )$$

In the formula, f denotes a frequency, □ₘ denotes a magnetic flux amplitude, Bₘ denotes a magnetic flux density amplitude, S denotes the area of the section of the core, and
k₁, k₂, k₁₁, and k₂₂ are computed through Formula (14) to Formula (17).

$${k}_{1} = {U}_{m , open} / {U}_{sin , open} \qquad ( 14 )$$

$${k}_{2} = {U}_{m , short} / {U}_{sin , short} \qquad ( 15 )$$

$${k}_{11} = {lim}_{S \to 0} \frac{{k}_{1}}{S} = {lim}_{S \to 0} \frac{{U}_{m , open} / S}{{U}_{sin , open}} = \frac{{B}_{m , open}}{{ψ}_{m , open}} \qquad ( 16 )$$

$${k}_{22} = {lim}_{S \to 0} \frac{{k}_{2}}{S} = {lim}_{S \to 0} \frac{{U}_{m , short} / S}{{U}_{sin , short}} = \frac{{B}_{m , short}}{{ψ}_{m , short}} \qquad ( 17 )$$

In the formula, U_{m,open} and U_{m,short} denote an EMV amplitude calculated under an open-circuit condition and an EMV amplitude calculated under a short-circuit condition respectively, B_{m,open} and B_{m,short} denote a magnetic flux density amplitude calculated under an open-circuit condition and a magnetic flux density amplitude calculated under a short-circuit condition respectively, U_{sin,open} and U_{sin,short} denote an open-circuit excitation voltage amplitude and a short-circuit excitation voltage amplitude respectively, and ψ_{m,open} and ψ_{m,short} denote a flux linkage amplitude under an open-circuit condition and a flux linkage amplitude under a short-circuit condition respectively.

In a preferred implementation of the method, the nanocrystalline core is modeled based on a homogenized solid body instead of a layered stacked structure, and an anisotropic magnetic conductivity and an electrical conductivity of the core are expressed as follows:

$$\{ \begin{matrix}{μ}_{r} = {μ}_{d} = F {μ}_{m} + ( 1 - F ) {μ}_{0} \\ {μ}_{n} = \frac{{μ}_{0} {μ}_{m}}{( 1 - F ) {μ}_{m} + F {μ}_{0}}\end{matrix} \qquad ( 18 )$$

$$\{ \begin{matrix}{σ}_{r} = {σ}_{d} = F {σ}_{m} \\ {σ}_{n} = {( \frac{d}{D} )}^{2} \frac{1}{F} {σ}_{m}\end{matrix} \qquad ( 19 )$$

In the formula, μᵣ, μ_{d}, and μₙ denote an equivalent magnetic conductivity of the nanocrystalline core in a winding direction, an equivalent magnetic conductivity of the nanocrystalline core in a thickness direction, and an equivalent magnetic conductivity of the nanocrystalline core in a normal direction respectively, σᵣ, σ_{d}, and σₙ denote an equivalent electrical conductivity of the nanocrystalline core in the winding direction, an equivalent electrical conductivity of the nanocrystalline core in the thickness direction, and an equivalent electrical conductivity of the nanocrystalline core in the normal direction respectively, F denotes a filling coefficient, μ₀ denotes a magnetic conductivity in vacuum, Uₘ denotes a magnetic conductivity of a strip, σₘ denotes an electrical conductivity of the strip, d denotes a thickness of the strip, and D denotes a width of the core.

In a preferred implementation of the method, the finite element simulation is COMSOL Multiphysics, Ansys, or Maxwell.

In an embodiment, since the magnetic flux density cannot be directly measured. Based on Faraday's law of electromagnetic induction, the equivalent magnetization voltage (EMV) is provided to characterize the average magnetic flux density passing through the particular section of the core. The equivalent magnetization voltage (EMV) is defined as follows:

$${u}_{m} ( t ) = \frac{d ϕ ( t )}{dt} = \frac{d}{dt} \int B ( t ) dS = S \frac{{dB}_{ave} ( t )}{dt} \qquad ( 1 )$$

In the formula, uₘ(t) denotes the equivalent magnetization voltage of the section S of the core, □(t) denotes a magnetic flux passing through the section, B(t) denotes a magnetic flux density, and Bₐᵥₑ(t) denotes the average magnetic flux density in the section. A schematic diagram of time domain waveforms of uₘ(t) and B(t) are shown in FIG. 1.

When the core is not saturated, the magnetic conductivity of the core is approximately a constant value. According to a superposition principle, the magnetic flux □_{load} in the nanocrystalline core under a load condition is equal to the sum of the main flux □ₘₐᵢₙ under an open-circuit condition and the leakage flux □_{leakage} under a short-circuit condition, that is,

$${ϕ}_{load} = {ϕ}_{main} + {ϕ}_{leakage} \qquad ( 2 )$$

Based on Formula (1), the EMVu_{m,load} of the particular section of the nanocrystalline core under a load condition is equal to the sum of the EMVu_{m,open} of the section under an open-circuit condition and the EMVu_{m,short} of the section under a short-circuit condition, that is,

$${u}_{m , load} = {u}_{m , open} + {u}_{m , short} \qquad ( 3 )$$

Based on Fourier superposition principle, the open circuit voltage uₒₚₑₙ and the short circuit voltage uₛₕₒᵣₜ may be expressed as follows:

$${u}_{open} = {\sum }_{i = 1}^{n} {u}_{open , sin , n} \qquad ( 4 )$$

$${u}_{short} = {\sum }_{i = 1}^{n} {u}_{short , sin , n} \qquad ( 5 )$$

In the formula, u_{open,sin,n} denotes the n^{th} harmonic component of the open circuit voltage, and u_{short,sin,n} denotes the n^{th} harmonic component of the short circuit voltage. Since a higher harmonic component amplitude of the open circuit voltage and a higher harmonic component amplitude of the short circuit voltage are very small, and the magnetic conductivity of the nanocrystalline strip varies little along with a frequency at low frequencies, the magnetic conductivity of the core may be approximately considered to be unchanged along with the frequency and the same as the magnetic conductivity of the core at a fundamental frequency. Thus, the magnetic flux distribution in the nanocrystalline core does not change along with the frequency, and a magnetic flux distribution in the nanocrystalline core under non-sinusoidal excitation is the same as a magnetic flux distribution in the nanocrystalline core under fundamental frequency sinusoidal excitation. Thus, the EMVu_{m,open,n} under the n^{th} harmonic excitation of the open circuit voltage and the EMVu_{m,short,n} under the n^{th} harmonic excitation of the short circuit voltage may be expressed as follows:

$${u}_{m , open , n} = {k}_{1} {u}_{open , sin , n} \qquad ( 6 )$$

$${u}_{m , short , n} = {k}_{2} {u}_{short , sin , n} \qquad ( 7 )$$

In the formula, k₁ denotes the coefficient related to the main flux distribution in the core under open-circuit sinusoidal excitation, and k₂ denotes the coefficient related to the leakage flux distribution in the core under short-circuit sinusoidal excitation, and by combining Formula (4) to Formula (7), the EMV under an open-circuit condition and the EMV under a short-circuit condition may be expressed as follows:

$${u}_{m , open} = {\sum }_{i = 1}^{n} {u}_{m , open , n} = {k}_{1} {\sum }_{i = 1}^{n} {u}_{open , sin , n} = {k}_{1} {u}_{open} \qquad ( 8 )$$

$${u}_{m , short} = {\sum }_{i = 1}^{n} {u}_{m , short , n} = {k}_{2} {\sum }_{i = 1}^{n} {u}_{short , sin , n} = {k}_{2} {u}_{short} \qquad ( 9 )$$

By combining Formula (3), Formula (8), and Formula (9), the EMV of the particular section in the nanocrystalline core under a load condition may be expressed as follows:

$${u}_{m , load} = {k}_{1} {u}_{open} + {k}_{2} {u}_{short} \qquad ( 10 )$$

Through the integral operation or an inverse operation of Formula (1), the average magnetic flux density in the section of the core may be expressed as follows:

$${B}_{ave} ( t ) = \frac{1}{S} \int {u}_{m , load} dt = \frac{1}{S} \int ( {k}_{1} {u}_{open} + {k}_{2} {u}_{short} ) dt \qquad ( 11 )$$

When S approaches zero, Formula (11) is changed into

$$\begin{matrix}B ( t ) = {lim}_{S \to 0} \frac{1}{S} \int ( {k}_{1} {u}_{open} + {k}_{2} {u}_{short} ) dt \\ = {lim}_{S \to 0} \frac{1}{S} \int ( {k}_{1} {u}_{open} dt + {k}_{2} {u}_{short} dt ) \\ = {lim}_{S \to 0} \frac{1}{S} ( {k}_{1} {ψ}_{open} + {k}_{2} {ψ}_{short} ) \\ = ( {k}_{11} {ψ}_{open} + {k}_{22} {ψ}_{short} )\end{matrix} \qquad ( 12 )$$

In the formula, ψₒₚₑₙ and ψₛₕₒᵣₜ denote the total flux linkage under an open-circuit condition and the total flux linkage under a short-circuit condition respectively, k₁₁ is the coefficient related to the main flux density distribution in the core under the open-circuit sinusoidal excitation, and k₂₂ is the coefficient related to the leakage flux density distribution in the core under the short-circuit sinusoidal excitation.

A simplified flowchart of the method is shown in FIG. 2.

The coefficient k₁, the coefficient k₂, the coefficient k₁₁, and the coefficient k₂₂ are calculated through finite element simulation. The magnetic flux density distribution in the nanocrystalline core under an open-circuit condition and the magnetic flux density distribution in the nanocrystalline core under a short-circuit condition are calculated through the frequency domain simulation at first, and then the amplitude Uₘ of the equivalent magnetization voltage (EMV) of the section of the core is calculated through Formula (13).

$${U}_{m} = {ωϕ}_{m} = ω \int {B}_{m} \cdot dS = 2 π f \int {B}_{m} \cdot dS \qquad ( 13 )$$

In the formula, f denotes the frequency, □ₘ denotes the magnetic flux amplitude, Bₘ denotes the magnetic flux density amplitude, and S denotes the area of the section of the core.

And k₁, k₂, k₁₁, and k₂₂ are computed through Formula (14) to Formula (17).

$${k}_{1} = {U}_{m , open} / {U}_{sin , open} \qquad ( 14 )$$

$${k}_{2} = {U}_{m , short} / {U}_{sin , short} \qquad ( 15 )$$

$${k}_{11} = {lim}_{S \to 0} \frac{{k}_{1}}{S} = {lim}_{S \to 0} \frac{{U}_{m , open} / S}{{U}_{sin , open}} = \frac{{B}_{m , open}}{{ψ}_{m , open}} \qquad ( 16 )$$

$${k}_{22} = {lim}_{S \to 0} \frac{{k}_{2}}{S} = {lim}_{S \to 0} \frac{{U}_{m , short} / S}{{U}_{sin , short}} = \frac{{B}_{m , short}}{{ψ}_{m , short}} \qquad ( 17 )$$

In the formula, U_{m,open} and U_{m,short} denote the EMV amplitude calculated under an open-circuit condition and the EMV amplitude calculated under a short-circuit condition respectively, B_{m,open} and B_{m,short} denote the magnetic flux density amplitude calculated under an open-circuit condition and the magnetic flux density amplitude calculated under a short-circuit condition respectively, U_{sin,open} and U_{sin,short} denote the open-circuit excitation voltage amplitude and the short-circuit excitation voltage amplitude respectively, and ψ_{m,open} and ψ_{m,short} denote the flux linkage amplitude under an open-circuit condition and the flux linkage amplitude under a short-circuit condition respectively.

Since the electrical conductivity and the magnetic conductivity of the nanocrystalline core are anisotropic, a homogenized finite element model may be used to calculate the magnetic flux density in the core. The nanocrystalline core is modeled by adopting a homogenized solid body shown in FIG. 3 instead of a layered stacked structure, and the anisotropic magnetic conductivity and an electrical conductivity of the core may be expressed as follows:

$$\{ \begin{matrix}{μ}_{r} = {μ}_{d} = F {μ}_{m} + ( 1 - F ) {μ}_{0} \\ {μ}_{n} = \frac{{μ}_{0} {μ}_{m}}{( 1 - F ) {μ}_{m} + F {μ}_{0}}\end{matrix} \qquad ( 18 )$$

$$\{ \begin{matrix}{σ}_{r} = {σ}_{d} = F {σ}_{m} \\ {σ}_{n} = {( \frac{d}{D} )}^{2} \frac{1}{F} {σ}_{m}\end{matrix} \qquad ( 19 )$$

In the formula, μᵣ, μ_{d}, and μₙ denote an equivalent magnetic conductivity of the nanocrystalline core in a winding direction, an equivalent magnetic conductivity of the nanocrystalline core in a thickness direction, and an equivalent magnetic conductivity of the nanocrystalline core in a normal direction respectively, σᵣ, σ_{d}, and σₙ denote an equivalent electrical conductivity of the nanocrystalline core in the winding direction, an equivalent electrical conductivity of the nanocrystalline core in the thickness direction, and an equivalent electrical conductivity of the nanocrystalline core in the normal direction respectively, F denotes a filling coefficient, μ₀ denotes a magnetic conductivity in vacuum, μₘ denotes a magnetic conductivity of a strip, σₘ denotes an electrical conductivity of the strip, d denotes a thickness of the strip, and D denotes a width of the core.

With a single-phase-shift dual-active-bridge (DAB) converter as an example, specific implementation steps of the method are analyzed. FIG. 4 shows a calculation process of the EMV and the magnetic flux density distribution of the nanocrystalline core based on a superposition principle. A primary voltage and a secondary voltage of the transformer are u_{AB} and u_{CD} respectively, and a load condition of the single-phase-shift DAB converter may be decomposed into an open-circuit condition with an excitation voltage of u_{AB} and a short-circuit condition with an excitation voltage of u_{AB}-u_{CD} that are subjected to superposition. According to the superposition principle, the EMV of the section of the core under a load condition is equal to the sum of the EMV of the section of the core under an open-circuit condition and the EMV of the section of the core under a short-circuit condition. Based on Formula (10), the EMV of the section of the core under a load condition may be expressed as follows:

$${u}_{m , DAB} = {k}_{1 , DAB} {u}_{CD} + {k}_{2 , DAB} ( {u}_{AB} - {u}_{CD} ) \qquad ( 20 )$$

Through the finite element simulation calculation and Formula (11) and Formula (12), the average magnetic flux density of the sections of the core and the magnetic flux density distribution in the core may be calculated.

A system for calculating a magnetic flux density distribution in a nanocrystalline high-frequency transformer core under a load condition includes:
a load measuring unit configured to characterize, under a load condition, an average magnetic flux density passing through a section S in the nanocrystalline high-frequency transformer core by adopting an equivalent magnetization voltage, where a magnetic flux □_{load} in the nanocrystalline core under a load condition is equal to a sum of a main flux □ₘₐᵢₙ under an open-circuit condition and a leakage flux □_{leakage} under a short-circuit condition, that is, φ_{load}=φₘₐᵢₙ+φ_{leakage} and an EMVu_{m,load} of a particular section S of the nanocrystalline core under a load condition is equal to a sum of an EMVu_{m,open} of the section under an open-circuit condition and an EMVu_{m,short} of the section under a short-circuit condition, that is, u_{m,load}=u_{m,open}+u_{m,short};

a voltage calculating unit configured to calculate, based on Fourier superposition principle, an open circuit voltage uₒₚₑₙ and a short circuit voltage uₛₕₒᵣₜ, where the open circuit voltage uₒₚₑₙ and the short circuit voltage uₛₕₒᵣₜ are expressed as follows:

$${u}_{open} = {\sum }_{i = 1}^{n} {u}_{open , sin , n} , {u}_{short} = {\sum }_{i = 1}^{n} {u}_{short , sin , n}$$

in the formula, u_{open,sin,n} denotes an n^{th} harmonic component of the open circuit voltage, and u_{short,sin,n} denotes an n^{th} harmonic component of the short circuit voltage, and an EMVu_{m,open,n} under n^{th} harmonic excitation of the open circuit voltage and an EMVu_{m,short} under n^{th} harmonic excitation of the short circuit voltage are expressed as follows:
u_{m,open,n}=k₁u_{open,sin,n}, u_{m,short,n}=k₂u_{short,sin,n}, in the formula, k₁ denotes a coefficient related to a main flux distribution in the core under open-circuit sinusoidal excitation, and k₂ denotes a coefficient related to a leakage flux distribution in the core under short-circuit sinusoidal excitation, and an EMV under an open-circuit condition and an EMV under a short-circuit condition are expressed as follows:

$${u}_{m , open} = {\sum }_{i = 1}^{n} {u}_{m , open , n} = {k}_{1} {\sum }_{i = 1}^{n} {u}_{open , sin , n} = {k}_{1} {u}_{open} , {u}_{m , short} = {\sum }_{i = 1}^{n} {u}_{m , short , n} = {k}_{2} {\sum }_{i = 1}^{n} {u}_{short , sin , n} = {k}_{2} {u}_{short} ,$$

and
the EMV of the section S in the nanocrystalline core under a load condition is expressed as follows:

$${u}_{m , load} = {k}_{1} {u}_{open} + {k}_{2} {u}_{short} ;$$

and
an integral unit configured to express, through an integral operation, the average magnetic flux density in the section S in the core as follows:

$${B}_{ave} ( t ) = \frac{1}{S} \int {u}_{m , load} dt = \frac{1}{S} \int ( {k}_{1} {u}_{open} + {k}_{2} {u}_{short} ) dt .$$

In the system, the integral unit includes a finite element simulation unit for calculating the average magnetic flux density in the section S of the core.

In the system, the finite element simulation unit is COMSOL Multiphysics, Ansys, or Maxwell.

A computer storage medium includes computer instructions. The computer instructions cause a computer to perform the method when run on the computer.

### An Electronic Device Includes:

a memory, a processor, and a computer program that is stored in the memory and is runnable on the processor.

The processor implements the method when executing the program.

Although the implementation solutions of the present disclosure have been described above in conjunction with the accompanying drawings, the present disclosure is not limited to the specific implementation solutions and application fields, and the specific implementation solutions are merely illustrative and instructive rather than limitative. Those of ordinary skill in the art can further make many forms under the inspiration of this description and without departing from the protection scope of the claims of the present disclosure. Those forms are still protected by the present disclosure.

1. A method for calculating a magnetic flux density distribution in a nanocrystalline high-frequency transformer core under a load condition, comprising:
under a load condition, an average magnetic flux density passing through a section S in the nanocrystalline high-frequency transformer core by adopting an equivalent magnetization voltage, wherein a magnetic flux □_{load} in the nanocrystalline core under a load condition is equal to a sum of a main flux □ₘₐᵢₙ under an open-circuit condition and a leakage flux □_{leakage} under a short-circuit condition, that is, φ_{load}=φₘₐᵢₙ+φ_{leakage}, and an EMVu_{m,load} of a particular section S of the nanocrystalline core under a load condition is equal to a sum of an EMVu_{m,open} of the section under an open-circuit condition and an EMVu_{m,short} of the section under a short-circuit condition, that is,
$${u}_{m , load} = {u}_{m , open} + {u}_{m , short} ;$$
expressing, based on Fourier superposition principle, an open circuit voltage uₒₚₑₙ and a short circuit voltage uₛₕₒᵣₜ as follows:
$${u}_{open} = {\sum }_{i = 1}^{n} {u}_{open , sin , n} , {u}_{short} = {\sum }_{i = 1}^{n} {u}_{short , sin , n} ,$$
in the formula, u_{open,sin,n} denotes an n^{th} harmonic component of the open circuit voltage, and u_{short,sin,n} denotes an n^{th} harmonic component of the short circuit voltage, and an EMVu_{m,open,n} under n^{th} harmonic excitation of the open circuit voltage and an EMVu_{m,short,n} under n^{th} harmonic excitation of the short circuit voltage are expressed as follows:
u_{m,open,n}=k₁u_{open,sin,n}, u_{m,short,n}=k₂u_{short,sin,n} in the formula, k₁ denotes a coefficient related to a main flux distribution in the core under open-circuit sinusoidal excitation, and k₂ denotes a coefficient related to a leakage flux distribution in the core under short-circuit sinusoidal excitation, and an EMV under an open-circuit condition and an EMV under a short-circuit condition are expressed as follows:
$${u}_{m , open} = {\sum }_{i = 1}^{n} {u}_{m , open , n} = {k}_{1} {\sum }_{i = 1}^{n} {u}_{open , sin , n} = {k}_{1} {u}_{open} , {u}_{m , short} = {\sum }_{i = 1}^{n} {u}_{m , short , n} = {k}_{2} {\sum }_{i = 1}^{n} {u}_{short , sin , n} = {k}_{2} {u}_{short} ,$$
and the EMV of the section S in the nanocrystalline core under a load condition is expressed as follows:
$${u}_{m , load} = {k}_{1} {u}_{open} + {k}_{2} {u}_{short} ;$$
and expressing, through an integral operation, the average magnetic flux density in the section S in the core as follows:
$${B}_{ave} ( t ) = \frac{1}{S} \int {u}_{m , load} dt = \frac{1}{S} \int ( {k}_{1} {u}_{open} + {k}_{2} {u}_{short} ) dt .$$

2. The method according to claim 1, wherein, when an area S of the section S of the core approaches zero,
$$\begin{matrix}B ( t ) = {lim}_{S \to 0} \frac{1}{S} \int ( {k}_{1} {u}_{open} + {k}_{2} {u}_{short} ) dt \\ = {lim}_{S \to 0} \frac{1}{S} \int ( {k}_{1} {u}_{open} dt + {k}_{2} {u}_{short} dt ) \\ = {lim}_{S \to 0} \frac{1}{S} ( {k}_{1} {ψ}_{open} + {k}_{2} {ψ}_{short} ) \\ = ( {k}_{11} {ψ}_{open} + {k}_{22} {ψ}_{short} )\end{matrix} ,$$
in the formula, ψₒₚₑₙ and ψₛₕₒᵣₜ denote a total flux linkage under an open-circuit condition and a total flux linkage under a short-circuit condition respectively, a coefficient k₁₁ is a coefficient related to a main flux density distribution in the core under the open-circuit sinusoidal excitation, and a coefficient k₂₂ is a coefficient related to a leakage flux density distribution in the core under the short-circuit sinusoidal excitation.

3. The method according to claim 1, wherein the equivalent magnetization voltage (EMV) is expressed as follows:
$${u}_{m} ( t ) = \frac{d ϕ ( t )}{dt} = \frac{d}{dt} \int B ( t ) dS = S \frac{{dB}_{ave} ( t )}{dt} ,$$
in the formula, uₘ(t) denotes the equivalent magnetization voltage of the section S of the core, □(t) denotes a magnetic flux passing through the section, B(t) denotes a magnetic flux density, Bₐᵥₑ(t) denotes the average magnetic flux density in the section, and S denotes an area of the section S of the core.

4. The method according to claim 3, wherein the coefficient k₁, the coefficient k₂, the coefficient k₁₁, and the coefficient k₂₂ are calculated through finite element simulation, a magnetic flux density distribution in the nanocrystalline core under an open-circuit condition and a magnetic flux density distribution in the nanocrystalline core under a short-circuit condition are calculated through frequency domain simulation at first, and then an amplitude Uₘ of the equivalent magnetization voltage (EMV) of the section of the core is calculated as follows:
$${U}_{m} = {ωϕ}_{m} = ω \int {B}_{m} \cdot dS = 2 π f \int {B}_{m} \cdot dS ,$$
in the formula, f denotes a frequency, □ₘ denotes a magnetic flux amplitude, Bₘ denotes a magnetic flux density amplitude, S denotes the area of the section of the core, and k₁, k₂, k₁₁, and k₂₂ are expressed as follows:
$${k}_{1} = {U}_{m , open} / {U}_{sin , open} ,$$
$${k}_{2} = {U}_{m , short} / {U}_{sin , short} ,$$
$${k}_{11} = {lim}_{S \to 0} \frac{{k}_{1}}{S} = {lim}_{S \to 0} \frac{{U}_{m , open} / S}{{U}_{sin , open}} = \frac{{B}_{m , open}}{{ψ}_{m , open}} ,$$
$${k}_{22} = {lim}_{S \to 0} \frac{{k}_{2}}{S} = {lim}_{S \to 0} \frac{{U}_{m , short} / S}{{U}_{sin , short}} = \frac{{B}_{m , short}}{{ψ}_{m , short}} ,$$
in the formula, u_{m,open} and u_{m,short} denote an EMV amplitude calculated under an open-circuit condition and an EMV amplitude calculated under a short-circuit condition respectively, B_{m,open} and B_{m,short} denote a magnetic flux density amplitude calculated under an open-circuit condition and a magnetic flux density amplitude calculated under a short-circuit condition respectively, U_{sin,open} and U_{sin,short} denote an open-circuit excitation voltage amplitude and a short-circuit excitation voltage amplitude respectively, and ψ_{m,open} and ψ_{m,short} denote a flux linkage amplitude under an open-circuit condition and a flux linkage amplitude under a short-circuit condition respectively.

5. The method according to claim 1, wherein the nanocrystalline core is modeled based on a homogenized solid body instead of a layered stacked structure, and an anisotropic magnetic conductivity and an electrical conductivity of the core are expressed as follows:
$$\{ \begin{matrix}{μ}_{r} = {μ}_{d} = F {μ}_{m} + ( 1 - F ) {μ}_{0} \\ {μ}_{n} = \frac{{μ}_{0} {μ}_{m}}{( 1 - F ) {μ}_{m} + F {μ}_{0}}\end{matrix} ,$$
$$\{ \begin{matrix}{σ}_{r} = {σ}_{d} = F {σ}_{m} \\ {σ}_{n} = {( \frac{d}{D} )}^{2} \frac{1}{F} {σ}_{m}\end{matrix} ,$$
in the formula, μᵣ, μ_{d}, and μₙ denote an equivalent magnetic conductivity of the nanocrystalline core in a winding direction, an equivalent magnetic conductivity of the nanocrystalline core in a thickness direction, and an equivalent magnetic conductivity of the nanocrystalline core in a normal direction respectively, σᵣ, σ_{d}, and σₙ denote an equivalent electrical conductivity of the nanocrystalline core in the winding direction, an equivalent electrical conductivity of the nanocrystalline core in the thickness direction, and an equivalent electrical conductivity of the nanocrystalline core in the normal direction respectively, F denotes a filling coefficient, μ₀ denotes a magnetic conductivity in vacuum, μₘ denotes a magnetic conductivity of a strip, σₘ denotes an electrical conductivity of the strip, d denotes a thickness of the strip, and D denotes a width of the core.

6. A system for calculating a magnetic flux density distribution in a nanocrystalline high-frequency transformer core under a load condition, comprising:
a load measuring unit configured to characterize, under a load condition, an average magnetic flux density passing through a section S in the nanocrystalline high-frequency transformer core by adopting an equivalent magnetization voltage, wherein a magnetic flux □_{load} in the nanocrystalline core under a load condition is equal to a sum of a main flux □ₘₐᵢₙ under an open-circuit condition and a leakage flux □_{leakage} under a short-circuit condition, that is, φ_{load}=φₘₐᵢₙ+φ_{leakage}, and an EMVu_{m,load} of a particular section S of the nanocrystalline core under a load condition is equal to a sum of an EMVu_{m,open} of the section under an open-circuit condition and an EMVu_{m,short} of the section under a short-circuit condition, that is, u_{m,load}=u_{m,open}+u_{m,short};
a voltage calculating unit configured to calculate, based on Fourier superposition principle, an open circuit voltage uₒₚₑₙ and a short circuit voltage uₛₕₒᵣₜ, wherein the open circuit voltage uₒₚₑₙ and the short circuit voltage uₛₕₒᵣₜ are expressed as follows:
$${u}_{open} = {\sum }_{i = 1}^{n} {u}_{open , sin , n} , {u}_{short} = {\sum }_{i = 1}^{n} {u}_{short , sin , n} ,$$
in the formula, u_{open,sin,n} denotes an n^{th} harmonic component of the open circuit voltage, and u_{short,sin,n} denotes an n^{th} harmonic component of the short circuit voltage, and an EMVu_{m,open,n} under n^{th} harmonic excitation of the open circuit voltage and an EMVu_{m,short,n} under n^{th} harmonic excitation of the short circuit voltage are expressed as follows:
u_{m,open,n}=k₁u_{open,sin,n}, u_{m,short,n}=k₂u_{short,sin,n}, in the formula, k₁ denotes a coefficient related to a main flux distribution in the core under open-circuit sinusoidal excitation, and k₂ denotes a coefficient related to a leakage flux distribution in the core under short-circuit sinusoidal excitation, and an EMV under an open-circuit condition and an EMV under a short-circuit condition are expressed as follows:
$${u}_{m , open} = {\sum }_{i = 1}^{n} {u}_{m , open , n} = {k}_{1} {\sum }_{i = 1}^{n} {u}_{open , sin , n} = {k}_{1} {u}_{open} ,$$
$${u}_{m , short} = {\sum }_{i = 1}^{n} {u}_{m , short , n} = {k}_{2} {\sum }_{i = 1}^{n} {u}_{short , sin , n} = {k}_{2} {u}_{short} ,$$
and
the EMV of the section S in the nanocrystalline core under a load condition is expressed as follows:
$${u}_{m , load} = {k}_{1} {u}_{open} + {k}_{2} {u}_{short} ;$$
and
an integral unit configured to express, through an integral operation, the average magnetic flux density in the section S in the core as follows:
$${B}_{ave} ( t ) = \frac{1}{S} \int {u}_{m , load} dt = \frac{1}{S} \int ( {k}_{1} {u}_{open} + {k}_{2} {u}_{short} ) dt .$$

7. The system according to claim 6, wherein the integral unit comprises a finite element simulation unit for calculating the average magnetic flux density in the section S of the core.

8. The system according to claim 7, wherein the finite element simulation unit is COMSOL Multiphysics, Ansys, or Maxwell.

9. A computer storage medium, comprising computer instructions, wherein the computer instructions cause a computer to perform the method according to claim 1 when run on the computer.

10. An electronic device, comprising:
a memory, a processor, and a computer program that is stored in the memory and is runnable on the processor, wherein the processor implements the method according to claim 1 when executing the program.

11. The computer storage medium of claim 9, wherein when an area S of the section S of the core approaches zero,
$$\begin{matrix}B ( t ) = {lim}_{S \to 0} \frac{1}{S} \int ( {k}_{1} {u}_{open} + {k}_{2} {u}_{short} ) dt \\ = {lim}_{S \to 0} \frac{1}{S} \int ( {k}_{1} {u}_{open} dt + {k}_{2} {u}_{short} dt ) \\ = {lim}_{S \to 0} \frac{1}{S} \int ( {k}_{1} {ψ}_{open} + {k}_{2} {ψ}_{short} ) \\ = ( {k}_{11} {ψ}_{open} + {k}_{22} {ψ}_{short} )\end{matrix} ,$$
in the formula, ψₒₚₑₙ and ψₛₕₒᵣₜ denote a total flux linkage under an open-circuit condition and a total flux linkage under a short-circuit condition respectively, a coefficient k₁₁ is a coefficient related to a main flux density distribution in the core under the open-circuit sinusoidal excitation, and a coefficient k₂₂ is a coefficient related to a leakage flux density distribution in the core under the short-circuit sinusoidal excitation.

12. The computer storage medium of claim 9, wherein the equivalent magnetization voltage (EMV) is expressed as follows:
$${u}_{m} ( t ) = \frac{d ϕ ( t )}{dt} = \frac{d}{dt} \int B ( t ) dS = S \frac{{dB}_{ave} ( t )}{dt} ,$$
in the formula, uₘ(t) denotes the equivalent magnetization voltage of the section S of the core, □(t) denotes a magnetic flux passing through the section, B(t) denotes a magnetic flux density, Bₐᵥₑ(t) denotes the average magnetic flux density in the section, and S denotes an area of the section S of the core.

13. The computer storage medium of claim 12, wherein the coefficient k₁, the coefficient k₂, the coefficient k₁₁, and the coefficient k₂₂ are calculated through finite element simulation, a magnetic flux density distribution in the nanocrystalline core under an open-circuit condition and a magnetic flux density distribution in the nanocrystalline core under a short-circuit condition are calculated through frequency domain simulation at first, and then an amplitude Uₘ of the equivalent magnetization voltage (EMV) of the section of the core is calculated as follows:
$${U}_{m} = {ωϕ}_{m} = ω \int {B}_{m} \cdot dS = 2 π f \int {B}_{m} \cdot dS ,$$
in the formula, f denotes a frequency, □ₘ denotes a magnetic flux amplitude, Bₘ denotes a magnetic flux density amplitude, S denotes the area of the section of the core, and k₁, k₂, k₁₁, and k₂₂ are expressed as follows:
$$\begin{matrix}{k}_{1} = {U}_{m , open} / {U}_{sin , open} , \\ {k}_{2} = {U}_{m , short} / {U}_{sin , short} , \\ {k}_{11} = {lim}_{S \to 0} \frac{{k}_{1}}{S} = {lim}_{S \to 0} \frac{{U}_{m , open} / S}{{U}_{sin , open}} = \frac{{B}_{m , open}}{{ψ}_{m , open}} , \\ {k}_{22} = {lim}_{S \to 0} \frac{{k}_{2}}{S} = {lim}_{S \to 0} \frac{{U}_{m , short} / S}{{U}_{sin , short}} = \frac{{B}_{m , short}}{{ψ}_{m , short}} ,\end{matrix}$$
in the formula, u_{m,open} and u_{m,short} denote an EMV amplitude calculated under an open-circuit condition and an EMV amplitude calculated under a short-circuit condition respectively, B_{m,open} and B_{m,short} denote a magnetic flux density amplitude calculated under an open-circuit condition and a magnetic flux density amplitude calculated under a short-circuit condition respectively, U_{sin,open} and U_{sin,short} denote an open-circuit excitation voltage amplitude and a short-circuit excitation voltage amplitude respectively, and ψ_{m,open} and ψ_{m,short} denote a flux linkage amplitude under an open-circuit condition and a flux linkage amplitude under a short-circuit condition respectively.

14. The computer storage medium of claim 9, wherein the nanocrystalline core is modeled based on a homogenized solid body instead of a layered stacked structure, and an anisotropic magnetic conductivity and an electrical conductivity of the core are expressed as follows:
$$\{ \begin{matrix}{μ}_{r} = {μ}_{d} = F {μ}_{m} + ( 1 - F ) {μ}_{0} \\ {μ}_{n} = \frac{{μ}_{0} {μ}_{m}}{( 1 - F ) {μ}_{m} + F {μ}_{0}}\end{matrix} ,$$
$$\{ \begin{matrix}{σ}_{r} = {σ}_{d} = F {σ}_{m} \\ {σ}_{n} = {( \frac{d}{D} )}^{2} \frac{1}{F} {σ}_{m}\end{matrix} ,$$
in the formula, μᵣ, μ_{d}, and μₙ denote an equivalent magnetic conductivity of the nanocrystalline core in a winding direction, an equivalent magnetic conductivity of the nanocrystalline core in a thickness direction, and an equivalent magnetic conductivity of the nanocrystalline core in a normal direction respectively, σᵣ, σ_{d}, and σₙ denote an equivalent electrical conductivity of the nanocrystalline core in the winding direction, an equivalent electrical conductivity of the nanocrystalline core in the thickness direction, and an equivalent electrical conductivity of the nanocrystalline core in the normal direction respectively, F denotes a filling coefficient, μ₀ denotes a magnetic conductivity in vacuum, μₘ denotes a magnetic conductivity of a strip, σₘ denotes an electrical conductivity of the strip, d denotes a thickness of the strip, and D denotes a width of the core.

15. The electronic device of claim 10, wherein when an area S of the section S of the core approaches zero,
$$\begin{matrix}B ( t ) = {lim}_{S \to 0} \frac{1}{S} \int ( {k}_{1} {u}_{open} + {k}_{2} {u}_{short} ) dt \\ = {lim}_{S \to 0} \frac{1}{S} \int ( {k}_{1} {u}_{open} dt + {k}_{2} {u}_{short} dt ) \\ = {lim}_{S \to 0} \frac{1}{S} \int ( {k}_{1} {ψ}_{open} + {k}_{2} {ψ}_{short} ) \\ = ( {k}_{11} {ψ}_{open} + {k}_{22} {ψ}_{short} )\end{matrix} ,$$
in the formula, ψₒₚₑₙ and ψₛₕₒᵣₜ denote a total flux linkage under an open-circuit condition and a total flux linkage under a short-circuit condition respectively, a coefficient k₁₁ is a coefficient related to a main flux density distribution in the core under the open-circuit sinusoidal excitation, and a coefficient k₂₂ is a coefficient related to a leakage flux density distribution in the core under the short-circuit sinusoidal excitation.

16. The electronic device of claim 10, wherein the equivalent magnetization voltage (EMV) is expressed as follows:
$${u}_{m} ( t ) = \frac{d ϕ ( t )}{dt} = \frac{d}{dt} \int B ( t ) dS = S \frac{{dB}_{ave} ( t )}{dt} ,$$
in the formula, uₘ(t) denotes the equivalent magnetization voltage of the section S of the core, □(t) denotes a magnetic flux passing through the section, B(t) denotes a magnetic flux density, Bₐᵥₑ(t) denotes the average magnetic flux density in the section, and S denotes an area of the section S of the core.

17. The electronic device of claim 16, wherein the coefficient k₁, the coefficient k₂, the coefficient k₁₁, and the coefficient k₂₂ are calculated through finite element simulation, a magnetic flux density distribution in the nanocrystalline core under an open-circuit condition and a magnetic flux density distribution in the nanocrystalline core under a short-circuit condition are calculated through frequency domain simulation at first, and then an amplitude Uₘ of the equivalent magnetization voltage (EMV) of the section of the core is calculated as follows:
$${U}_{m} = {ωϕ}_{m} = ω \int {B}_{m} \cdot dS = 2 π f \int {B}_{m} \cdot dS ,$$
in the formula, f denotes a frequency, □ₘ denotes a magnetic flux amplitude, Bₘ denotes a magnetic flux density amplitude, S denotes the area of the section of the core, and k₁, k₂, k₁₁, and k₂₂ are expressed as follows:
$$\begin{matrix}{k}_{1} = {U}_{m , open} / {U}_{sin , open} , \\ {k}_{2} = {U}_{m , short} / {U}_{sin , short} , \\ {k}_{11} = {lim}_{S \to 0} \frac{{k}_{1}}{S} = {lim}_{S \to 0} \frac{{U}_{m , open} / S}{{U}_{sin , open}} = \frac{{B}_{m , open}}{{ψ}_{m , open}} , \\ {k}_{22} = {lim}_{S \to 0} \frac{{k}_{2}}{S} = {lim}_{S \to 0} \frac{{U}_{m , short} / S}{{U}_{sin , short}} = \frac{{B}_{m , short}}{{ψ}_{m , short}} ,\end{matrix}$$
in the formula, U_{m,open} and U_{m,short} denote an EMV amplitude calculated under an open-circuit condition and an EMV amplitude calculated under a short-circuit condition respectively, B_{m,open} and B_{m,short} denote a magnetic flux density amplitude calculated under an open-circuit condition and a magnetic flux density amplitude calculated under a short-circuit condition respectively, U_{sin,open} and U_{sin,short} denote an open-circuit excitation voltage amplitude and a short-circuit excitation voltage amplitude respectively, and ψ_{m,open} and ψ_{m,short} denote a flux linkage amplitude under an open-circuit condition and a flux linkage amplitude under a short-circuit condition respectively.

18. The electronic device of claim 10, wherein the nanocrystalline core is modeled based on a homogenized solid body instead of a layered stacked structure, and an anisotropic magnetic conductivity and an electrical conductivity of the core are expressed as follows:
$$\{ \begin{matrix}{μ}_{r} = {μ}_{d} = F {μ}_{m} + ( 1 - F ) {μ}_{0} \\ {μ}_{n} = \frac{{μ}_{0} {μ}_{m}}{( 1 - F ) {μ}_{m} + F {μ}_{0}}\end{matrix} ,$$
$$\{ \begin{matrix}{σ}_{r} = {σ}_{d} = F {σ}_{m} \\ {σ}_{n} = {( \frac{d}{D} )}^{2} \frac{1}{F} {σ}_{m}\end{matrix} ,$$
in the formula, μᵣ, μ_{d}, and μₙ denote an equivalent magnetic conductivity of the nanocrystalline core in a winding direction, an equivalent magnetic conductivity of the nanocrystalline core in a thickness direction, and an equivalent magnetic conductivity of the nanocrystalline core in a normal direction respectively, σᵣ, σ_{d}, and σₙ denote an equivalent electrical conductivity of the nanocrystalline core in the winding direction, an equivalent electrical conductivity of the nanocrystalline core in the thickness direction, and an equivalent electrical conductivity of the nanocrystalline core in the normal direction respectively, F denotes a filling coefficient, μ₀ denotes a magnetic conductivity in vacuum, μₘ denotes a magnetic conductivity of a strip, σₘ denotes an electrical conductivity of the strip, d denotes a thickness of the strip, and D denotes a width of the core.
